(19) United States
(12) Patent Application Publication
(10) Pub. No.: US 2026/0079402 A1
(43) Pub. Date: Mar. 19, 2026

(54) FILM FORMING APPARATUS, FILM FORMING METHOD, AND METHOD OF MANUFACTURING ARTICLE

(71) Applicant: CANON KABUSHIKI KAISHA, Tokyo (JP)

(72) Inventor: YOSHIHIRO MATSUOKA, Tochigi (JP)

(21) Appl. No.: 19/302,732

(22) Filed: Aug. 18, 2025

(30) Foreign Application Priority Data
Sep. 17, 2024 (JP) 2024-160363

(51) Int. Cl. G03F 7/16; G03F 7/00

(52) U.S. Cl. CPC G03F 7/16; G03F 7/70741

(57) ABSTRACT

A film forming apparatus forms a film of a curable composition on a substrate by bringing a member into contact with the curable composition. The film forming apparatus includes: a holding unit configured to adsorptively hold the member while coming into contact with a central portion of the member; and a pressure control unit configured to apply a pressure to a surface of the holding unit opposite to a surface holding the member to deform the holding unit and the member.

### BACKGROUND

### Field of the Technology

The present disclosure relates to a film forming apparatus, a film forming method, and a method of manufacturing an article.

### Description of the Related Art

To manufacture semiconductor devices, film forming apparatuses such as imprint apparatuses and planarization apparatuses that form films of curable compositions placed on substrates using members are known. The “members” refer to, for example, molds that have contact surfaces with irregularities that come into contact with the curable compositions, or planarization members of which contact surfaces are flat.

Planarization apparatuses are used to planarize substrates between stacking processes in semiconductor manufacturing processes. That is, in processes of manufacturing semiconductor devices, heights of the substrates change as more layers are added. The changes in the heights adversely affect subsequent layering processes.

To address this problem, planarization apparatuses are used to planarize substrates between stacking steps. In laser-based lithography, planarization reduces an influence of depth of focus (DOF) constraints, which improves a critical dimension (CD) and uniformity of the critical dimension.

For example, in inkjet-based adaptive planarization (IAP), a liquid organic material (curable composition) drops based on a step difference of a substrate, and a planarization member (a mold for planarization) called a “superstrate” is pressed onto the dropped liquid organic material. By irradiating the liquid organic material with ultraviolet light or the like with the substrate brought in contact with the mold and curing the material, it is possible to achieve an improvement in accuracy of planarization.

Japanese Patent Application Laid-open No. 2022-64288 discloses a method of improving spreading of a liquid organic material and reducing unfilled defects by maintaining a curvature of a superstrate constant during pressing, using an annular chuck assembly that includes a flexible portion having a central opening.

However, in the method disclosed in Japanese Patent Application Laid-Open No. 2022-64288, there is a problem that if rigidity of a planarization member is weak, a shape of the planarization member is considerably changed due to a change in pressure control and unfilled defects occur in a central region of the planarization member.

### SUMMARY

The present disclosure is directed to providing a film forming apparatus capable of accurately forming a film of a curable composition.

A film forming apparatus forms a film of a curable composition on a substrate by bringing a member into contact with the curable composition. The film forming apparatus includes: a holding unit configured to adsorptively hold the member while coming into contact with a central portion of the member; and a pressure control unit configured to apply a pressure to a surface of the holding unit opposite to a surface holding the member to deform the holding unit and the member.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating an example of a planarization system according to a first embodiment of the present disclosure.

FIG. 2 is a diagram illustrating an example of a schematic cross-section of a chuck assembly according to the first embodiment of the present disclosure.

FIG. 3 is a diagram illustrating an example of a schematic cross-section of the chuck assembly when a superstrate is curved according to the first embodiment of the present disclosure.

FIG. 4 is a diagram illustrating an example of a schematic cross-section of a chuck assembly with a cut-out central portion according to a second embodiment of the present disclosure.

FIG. 5 is a diagram illustrating an example of a schematic cross-section of a chuck assembly with a cut-out central portion on the rear side according to a third embodiment of the present disclosure.

FIG. 6 is a diagram illustrating an example of a schematic cross-section of a chuck assembly formed by combining a plurality of members according to a fourth embodiment of the present disclosure.

FIG. 7 is a flowchart illustrating an example of a planarization method according to a fifth embodiment of the present disclosure.

FIG. 8 is a diagram illustrating an example of a schematic cross-section of the chuck assembly when the superstrate is released from a plate.

### DESCRIPTION OF THE EMBODIMENTS

Embodiments of the present disclosure will be described below with reference to the drawings. However, the present disclosure is not limited to the embodiments to be described below. In the drawings, the same reference numerals denote the same members or elements, and repeated description thereof will be omitted or simplified.

### First Embodiment

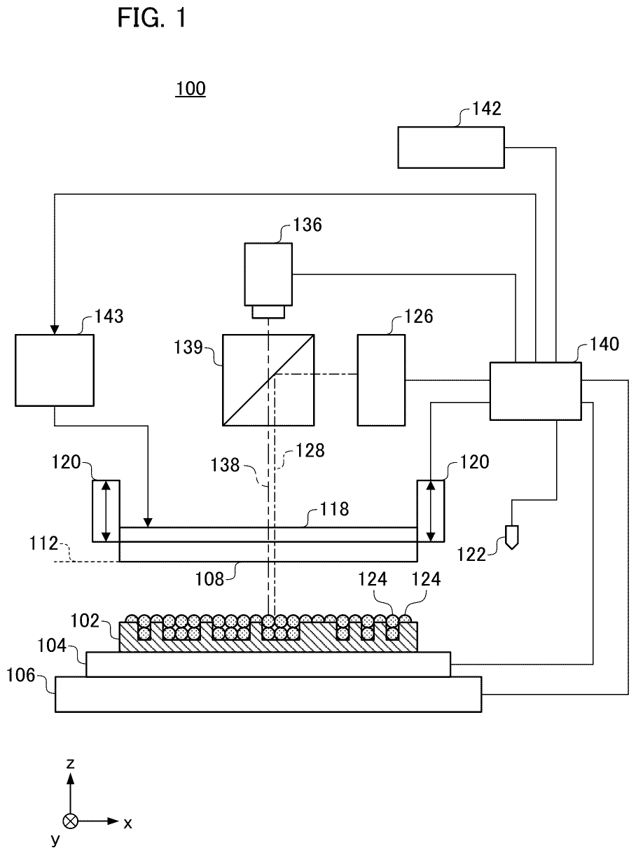

FIG. 1 is a schematic diagram illustrating an example of a planarization system according to a first embodiment of the present disclosure. Some of functional blocks illustrated in FIG. 1 are implemented by causing a CPU or the like serving as a computer (not illustrated) included in the planarization system to execute a computer program stored in a memory serving as a storage medium (not illustrated).

However, some or all of these functions may be implemented in hardware. As hardware, dedicated circuits (ASICs) or processors (such as reconfigurable processors or DSPs) can be used. Each functional block illustrated in FIG. 1 may not be contained in the same casing or may be configured by separate devices connected to each other via signal paths.

In the following description, an example of a film forming apparatus that forms a film of a curable composition by bringing a member into contact with the curable composition disposed on a substrate will be described using a planarization system 100 (planarization apparatus) as an example.

That is, the member of the film forming apparatus includes a planarization member of which a main portion of a contact surface coming into contact with the curable composition is a flat surface, and an example of the planarization system 100 serving as a planarization apparatus that forms a flat film of a curable composition by bringing the planarization member into contact with the curable composition disposed on the substrate will be described below.

However, the film forming apparatus according to the present disclosure is not limited to the planarization system 100, and includes, for example, an imprint apparatus. Here, the member of the imprint apparatus includes a mold that has an uneven contact surface coming into contact with a curable composition and forms a film with an unevenness by bringing the mold into contact with a curable composition disposed on the substrate.

The planarization system 100 is used to planarize a film of a curable composition 124 that has been applied to a substrate 102. The substrate 102 is held by a substrate chuck 104. The substrate chuck 104 may be a vacuum chuck, a pin-type chuck, a groove-type chuck, an electrostatic chuck, or an electromagnetic chuck, but is not limited thereto.

The substrate 102 and the substrate chuck 104 are further supported by a substrate positioning stage 106. The substrate positioning stage 106 is capable of executing, for example, a translational motion along the x, y, and z axes orthogonal to each other, as well as a rotational motion about the x, y, and z axes.

The substrate positioning stage 106, the substrate 102, and the substrate chuck 104 may be positioned on a base (not illustrated), and the substrate positioning stage 106 may be a part of a positioning system.

The substrate 102 is opposed to a superstrate 108 functioning as a member that forms a film of the curable composition by coming into contact with the curable composition disposed on the substrate, and has a flat working surface (contact surface) 112 facing the substrate 102. The substrate 102 and the superstrate 108 each have a disk-shaped form.

The superstrate 108 is formed of a material including fused silica, quartz, silicon, an organic polymer, a siloxane polymer, borosilicate glass, a fluorocarbon polymer, a metal, and hardened sapphire. Here, the superstrate 108 is not limited thereto.

In the present embodiment, the disk-shaped superstrate 108 is sufficiently transparent to UV light. The working surface 112 has an area equal to or slightly smaller than that of the surface of the disk-shaped substrate 102. The superstrate 108 may be coupled to or held by a chuck assembly 118, as will be described in more detail below.

The chuck assembly 118 is coupled to a planarization head 120 that is part of the positioning system. The planarization head 120 may be movably coupled to a bridge (not illustrated). The bridge is a structure that supports the planarization head 120 so that the planarization head 120 can move, for example, in the z-axis direction.

The planarization head 120 is configured to allow the chuck assembly 118 to execute a translational motion relative to the substrate 102 at least in the z-axis direction and further in the x-axis and y-axis directions and to allow the rotational movement about the x, y, and z axes. The planarization head 120 includes one or more actuators, such as a voice coil motor, a piezoelectric motor, a linear motor, or a nut-and-screw motor.

The planarization system 100 may also further include a fluid dispenser 122. The fluid dispenser 122 may be movably coupled to the above-described bridge. In the embodiment, the fluid dispenser 122 and the planarization head 120 share one or more of all the positioning constituents.

The fluid dispenser 122 and the planarization head 120 may also be configured to move independently of one another. The fluid dispenser 122 is used to deposit droplets of the curable composition 124 (curable composition) onto the substrate 102. The curable composition 124 is, for example, a resin such as a photocurable polymerizable material.

A volume of the deposited material may vary across the region of the substrate 102, based on at least a part of a topography profile. The fluid dispenser 122 may also use an inkjet technology to apply (eject) the curable composition 124.

As an example of the inkjet technology, any of thermal inkjet, inkjet of micro-electro-mechanical systems (MEMS), valve jet, and piezoelectric inkjet may be used.

The planarization system 100 includes a radiation source 126 that radiates chemical energy, for example, a radioactive ray such as ultraviolet (UV), along an exposure path 128. The planarization head 120 and the substrate positioning stage 106 are configured to position the superstrate 108 and the substrate 102 in alignment with the exposure path 128.

The radiation source 126 radiates chemical energy along the exposure path 128 after the superstrate 108 has come into contact with the curable composition 124. FIG. 1 illustrates the exposure path 128 when the superstrate 108 does not come into contact with the curable composition 124, but the exposure path 128 substantially does not change even when the superstrate 108 comes into contact with the curable composition 124.

The planarization system 100 further includes a camera 136. The camera 136 is used to inspect spreading of the curable composition 124 when the superstrate 108 comes into contact with the curable composition 124 during a planarization process.

In FIG. 1, reference numeral 138 denotes an optical axis of an imaging field of the camera 136. As illustrated in FIG. 1, the planarization system 100 includes one or more optical components 139 that combine a radioactive ray and light to be detected by the camera 136. The optical component 139 may include, for example, a dichroic mirror, a beam combiner, a prism, a lens, and a mirror.

The camera 136 is configured to detect a contrast between a region that is in contact with the curable composition 124 and a region that is not in contact on the lower surface of the superstrate 108. The camera 136 is configured with a CCD sensor, a CMOS sensor, a line camera, or a photodetector.

The camera 136 can acquire an image indicating a spread state of the curable composition 124 below the superstrate 108 or a separation state of the superstrate 108 from the cured curable composition 124. The camera 136 is also configured to measure interference fringes that change as the curable composition 124 spreads within a gap between the working surface 112 and the substrate surface.

Reference numeral 140 denotes a processor that includes a CPU and memory as a computer. Each unit of the planarization system 100 is adjusted and controlled by the processor 140. The processor 140 may include an MPU, a GPU, an ASIC, an FPGA, or a DSP.

The processor 140 may be a dedicated controller, or a general-purpose computer device configured as a controller. The foregoing memory includes a RAM and a ROM.

Reference numeral 143 denotes a pressure control unit that adsorptively holds the superstrate 108 on a plate 130 (holding unit) to be described below by supplying a predetermined air pressure to the chuck assembly 118. The pressure control unit also deforms both the plate 130 (holding unit) and the superstrate 108 (member) into a projection or recess shape.

That is, the pressure control unit 143 deforms both the holding unit and the member by applying a pressure from a side opposite to the surface of the plate 130 (holding unit) that holds the superstrate 108 (member). Further, the pressure control unit 143 supplies a predetermined pressure when detaching the superstrate 108 from the plate 130 or the like.

During the planarization process, a distance between the superstrate 108 and the substrate 102 is changed by either or both of the planarization head 120 and the substrate positioning stage 106. For example, the planarization head 120 is moved toward the substrate so that the superstrate 108 comes into contact with and spreads the droplets of the curable composition 124.

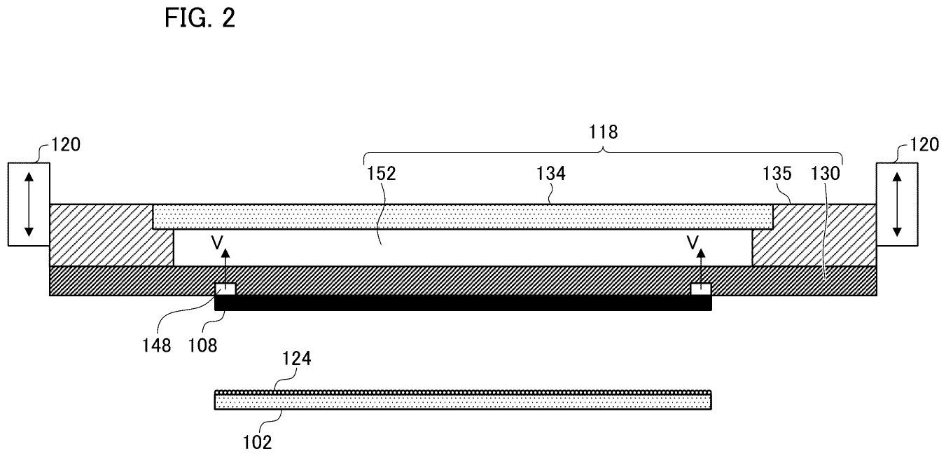

FIG. 2 is a diagram illustrating an example of a schematic cross-section of the chuck assembly 118 according to the first embodiment of the present disclosure. In FIG. 2, reference numeral 130 denotes a disk-shaped plate, reference numeral 134 denotes a disk-shaped cover, reference numeral 135 denotes a ring, and reference numeral 152 denotes a space enclosed by the plate 130, the cover 134, and the ring 135. These constituents form the chuck assembly 118.

Here, the plate 130 functions as a holding unit that adsorptively holds the superstrate 108 that is a member, while coming into contact with at least a central portion of the member.

Here, the “central portion” refers to a range up to 50% of a maximum radius from the center of the disk-shaped superstrate 108 that is the member. The center of the disk-shaped superstrate 108 that is the member is aligned with the center of the disk-shaped plate 130 that is the holding unit.

The plate 130 adsorptively holds the entire region of the superstrate 108 that is the member while being in contact with the entire region, and the radius of the plate 130 is greater than the radius of the superstrate 108.

The superstrate 108 that is the member is made of a material through which UV light and visible light can transmit. At least portions of the plate 130 and the cover 134 facing the superstrate 108 are made of materials through which UV light and visible light can transmit. That is, portions of the superstrate 108 that is the member, and the plate 130 or the cover 134 that is the holding unit facing the member are made of light-transmissive materials.

During the planarization process, when the superstrate and the substrate come into contact and the droplet of the curable composition 124 spreads, air or gas bubbles may become trapped between the superstrate 108 and the substrate 102, which can hinder the filling of the droplets.

To address this problem, in the planarization process according to the present embodiment, the superstrate 108 first comes into contact with the curable composition 124 at the center of the substrate 102, and then the contact region proceeds radially outward from the center to the periphery.

Therefore, by supplying a predetermined air pressure from the pressure control unit 143 to a space 152 on the rear side of the plate 130 included in the chuck assembly 118, the plate 130 is curved into a projection shape in advance, and thus the superstrate 108 is curved into a projection shape.

That is, the pressure control unit 143 deforms both the plate 130 that is the holding unit and the superstrate 108 that is the member into a projection shape toward the curable composition 124.

In the present embodiment, as illustrated in FIG. 2, the plate 130 includes a pressure space 148 (adsorption portion) enclosed by the plate 130 and the superstrate 108 in order to adsorptively hold the superstrate 108.

The pressure space 148 (adsorption portion) is configured as an annular space that adsorbs the outer edge portion of the superstrate 108. The pressure space 148 may be formed by a plurality of annular spaces provided in the plate 130 or a plurality of dispersed spaces, or a combination thereof.

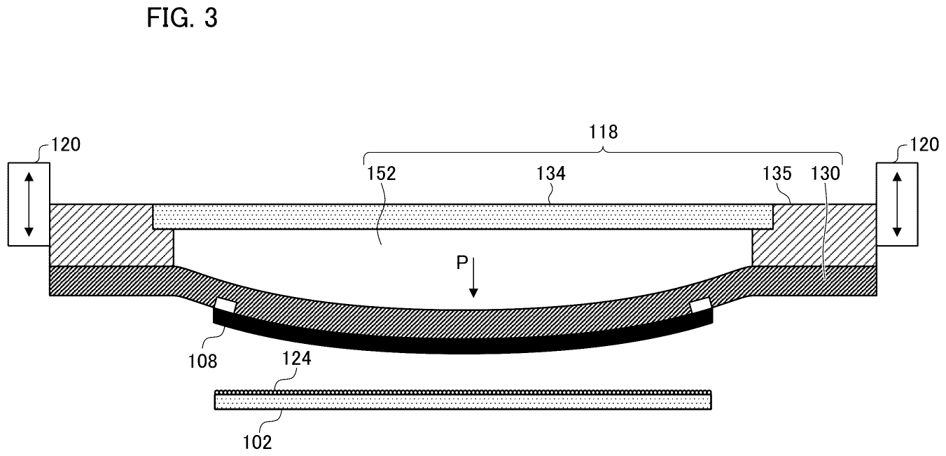

FIG. 3 is a diagram illustrating an example of a schematic cross-section of the chuck assembly 118 when a superstrate is curved according to the first embodiment of the present disclosure. As illustrated in FIG. 3, the superstrate 108 is curved into a projection shape by supplying a positive pressure P to the space 152. However, when an amount of deformation is too sensitive to the pressure, a change in pressure control may cause a variation in deflection of the center of the superstrate 108, that is, a position of a contact initiation point.

Therefore, in the present embodiment, sensitivity of deflection of the center of the superstrate 108 to the pressure in the space 152 is in the range of 0.01 to 1 μm/Pa. That is, a deflection amount of the central portion of the superstrate 108 that is the member to pressure is in the range of 0.01 to 1 μm/Pa.

Further, the deflection amount of the central portion of the superstrate 108 that is the member to pressure is in the range of 0.01 to 0.1 μm/Pa.

The following Formula (1) defines bending rigidity D. In Formula (1), His a thickness of the superstrate 108 or the plate 130, v is a Poisson's ratio of the superstrate 108 or the plate 130, and E is a Young's modulus of the superstrate 108 or the plate 130.

$$\begin{matrix}[ Math . 1 ] & \\ D = \frac{{EH}^{3}}{12 ( 1 - {v}^{2} )} & ( 1 )\end{matrix}$$

In the present embodiment, composite bending rigidity of the superstrate 108 and the plate 130 is in the range of 1 to 200 Pa·m³. That is, the composite bending rigidity in the central portion of the superstrate 108 that is the member and the plate 130 that is the holding unit is in the range of 1 to 200 Pa·m³.

According to Formula (1), for example, when the superstrate 108 has an elastic modulus of 70 GPa, a thickness of 0.7 mm, and a Poisson's ratio of 0.23, the bending rigidity is 2.12 Pa·m³.

In this case, to achieve composite bending rigidity of 20 Pa m³ of the superstrate 108 and the plate 130, the bending rigidity of the plate 130 is set in the range of 3 to 18 Pa·m³, depending on a bonding condition with the superstrate (such as degree of contact, friction, or the like).

That is, to ensure that the composite bending rigidity in the central portion of the member and the holding unit falls within a desired range, the bending rigidity of the central portion of the plate 130 that is the holding unit is set in accordance with the bending rigidity of the superstrate 108 that is the member.

The plate 130 may be made of the following material that has an elastic modulus (Young's modulus) of 1 to 210 GPa, 50 to 150 GPa, or 60 to 100 GPa. Specifically, the plate 130 may be formed of plastic (for example, acrylic), glass (for example, fused silica, borosilicate), metal (for example, aluminum, stainless steel), or ceramic (for example, zirconia, sapphire, alumina).

However, in the configuration illustrated in FIGS. 2 and 3 according to the first embodiment, rigidity may change in an outer peripheral portion of the superstrate, which also changes curvature induced by the positive pressure P in the outer edge portion.

As described above, according to the present embodiment, it is possible to provide a film forming apparatus capable of accurately forming a film of a curable composition.

### Second Embodiment

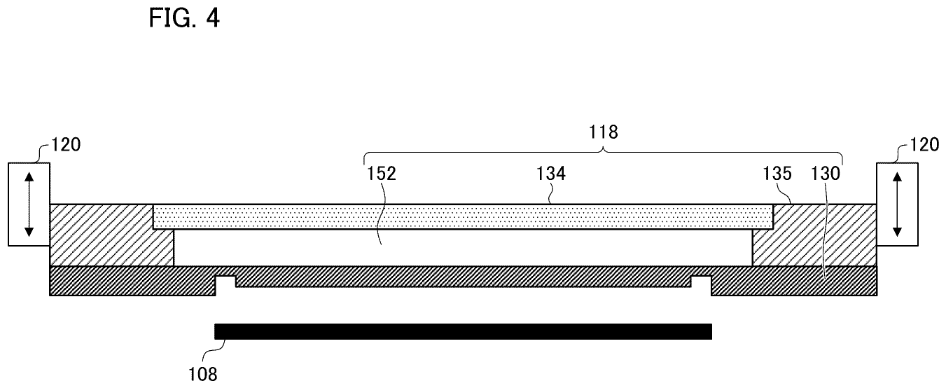

FIG. 4 is a diagram illustrating an example of a schematic cross-section of a chuck assembly 118 with a cut-out central portion according to a second embodiment of the present disclosure. As illustrated in FIG. 4, a portion of the plate 130 that holds the superstrate 108 is cut out. Accordingly, in the second embodiment of the present disclosure, overall rigidity of the superstrate 108 and the plate 130 is made uniform.

That is, by making the rigidity of the plate 130 that is the holding unit nonuniform, uniformity of the overall rigidity in the holding state of the superstrate 108 that is the member is enhanced. Therefore, by making the thickness of the region of the holding unit corresponding to the shape of the member nonuniform, the rigidity of the holding unit is made nonuniform and the uniformity of the overall rigidity in the holding state of the member is enhanced.

As one example, the bending rigidity of the superstrate 108 alone is set to 2.12 Pa·m³, and the overall uniform bending rigidity of the superstrate 108 and the plate 130 is set to 20 Pa·m³.

When the plate 130 is made of the same material as the superstrate (an elastic modulus of 70 GPa and a Poisson's ratio of 0.23), the thickness of a cut-out portion may be in the range of 0.8 to 1.4 mm depending on the bonding condition with the superstrate, and the thickness of a portion other than the cut-out portion may be 1.5 mm.

The cut-out portion in FIG. 4 is a circular recess, and a radius of the cut-out portion is set to be greater than the radius of the superstrate 108. This is because the deformation of the edge portion of the superstrate 108 is softened.

### Third Embodiment

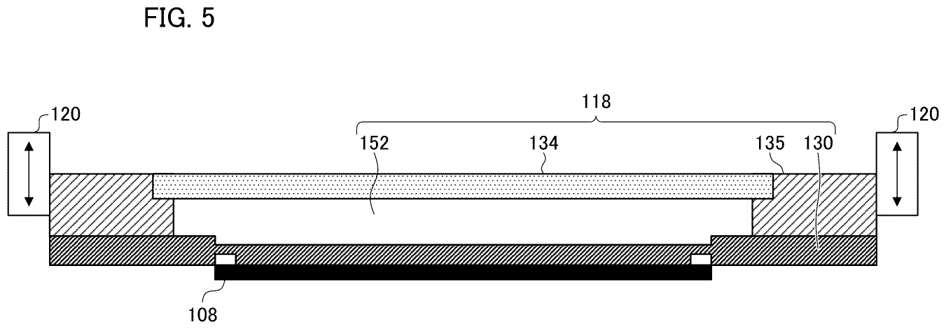

FIG. 5 is a diagram illustrating an example of a schematic cross-section of a chuck assembly 118 with a cut-out central portion on the rear side according to a third embodiment of the present disclosure. As illustrated in FIG. 5, the cut-out portion of the plate 130 may be formed on a side opposite to the side that holds the superstrate.

In the present embodiment, by making the thickness of the region of the holding unit corresponding to the shape of the member nonuniform, the rigidity of the holding unit is made nonuniform, and thus the uniformity of the overall rigidity in the holding state of the member is enhanced.

The cut-out portion in FIG. 5 is a circular recess, and a radius of the cut-out portion is set to be greater than the radius of the superstrate 108. This is for alleviating the deformation at the edge portion of the superstrate 108.

As one example, the bending rigidity of the superstrate 108 alone is set to 2.12 Pa·m³, and the overall uniform bending rigidity of the superstrate 108 and the plate 130 is set to 20 Pa·m³.

When the plate 130 is softer than the superstrate and has an elastic modulus of 3.2 GPa and a Poisson's ratio of 0.35, the thickness of the cut-out portion may be set to 2 to 3.9 mm depending on the bonding condition with the superstrate 108, and the thickness of the portion other than the cut-out portion may be set to 4 mm.

A difference between thicknesses of the cut-out portion and the portion other than the cut-out portion corresponds to a cut-out depth. When this depth exceeds the thickness of the superstrate 108, the superstrate 108 becomes embedded into the plate 130 in the configuration of FIG. 4. Accordingly, the configuration of FIG. 5 according to the third embodiment is more appropriate.

### Fourth Embodiment

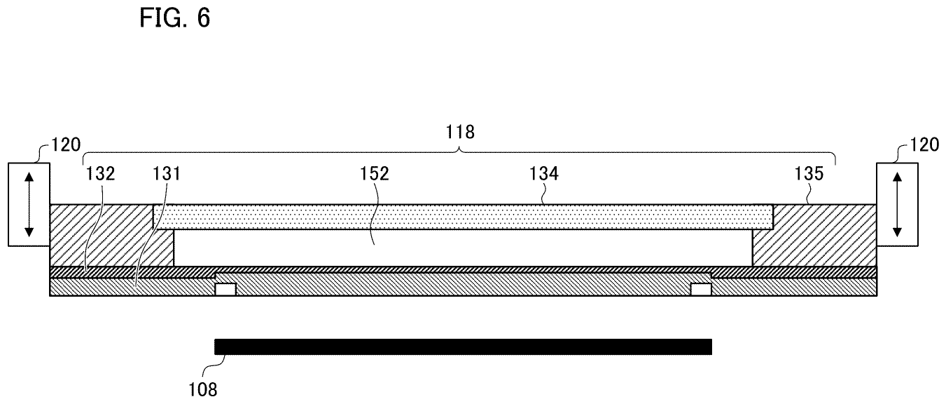

FIG. 6 is a diagram illustrating an example of a schematic cross-section of a chuck assembly 118 formed by combining a plurality of members according to a fourth embodiment of the present disclosure. In the fourth embodiment, a plurality of plates are used in order to reduce the rigidity of the central part of the plate compared to the peripheral part.

In the present embodiment, by making the thickness of the region of the holding unit corresponding to the shape of the member nonuniform, the rigidity of the holding unit is made nonuniform, and thus the overall rigidity uniformity in the holding state of the member is enhanced.

Considering that the composite rigidity with the plate increases when the superstrate 108 is adsorbed, the composite rigidity at the center of the superstrate 108 can be reduced by combining the plates 131 and 132.

That is, by configuring the holding unit from the plurality of plates 131 and 132 with nonuniform rigidity in combination, it is possible to enhance uniformity of the overall rigidity of the holding unit in the holding state of the member.

In the example of FIG. 6, the plates 131 and 132 are disk-shaped plates and form the chuck assembly 118 along with the cover 134, the ring 135, and the space 152.

In the example of FIG. 6, the rigidity of the plate 131 is lower than that of the plate 132. The thickness of the projected circular portion of the central portion of the plate 131 is greater than that of the outside (peripheral portion) of the circular portion of the central portion of the plate 131.

The radius of the projected circular portion of the central portion of plate 131 is set to be greater than the radius of the superstrate 108. This is because the deformation in the edge portion of the superstrate 108 is softened.

The combined thickness of the plates 131 and 132 is generally uniform as a whole. Accordingly, the composite rigidity near the center of the plate 131 can be made lower than that in the outside (peripheral portion). The plates 131 and 132 are transparent to UV light.

### Fifth Embodiment

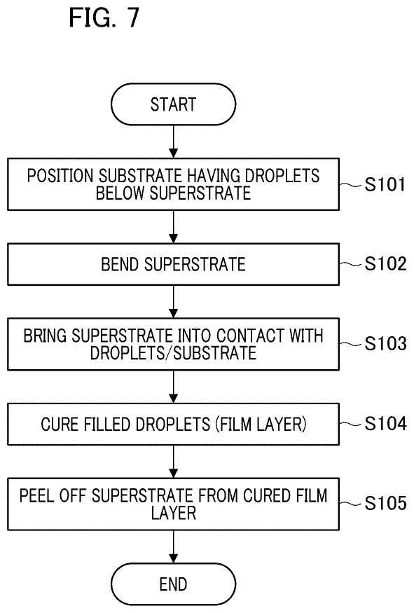

FIG. 7 is a flowchart illustrating an example of a planarization method according to a fifth embodiment of the present disclosure. Operations of steps in the flowchart of FIG. 7 are sequentially performed by causing a CPU or another processor serving as a computer in the processor 140 to execute a computer program stored in a memory. The example of the planarization method in FIG. 7 will be described using the configuration of the first embodiment illustrated in FIGS. 2 and 3. The example of the planarization method can also be applied to the configurations of the second to fourth embodiments.

In step S101, the substrate 102 to which droplets of the curable composition 124 is applied is transported and positioned below the superstrate 108. Before step S101 is performed, the droplets of the curable composition 124 have already been applied to the substrate by the fluid dispenser 122. Before step S101, the chuck assembly 118 adsorptively holds the superstrate 108 by absorbing the pressure space 148.

In step S102, as illustrated in FIG. 3, the superstrate 108 is bent into a projection shape by applying the positive pressure P to the space 152. That is, while the plate 130 is bent with being absorbed and held to the superstrate 108 via the pressure space 148, as illustrated in FIG. 3, the superstrate 108 coming into contact with plate 130 is also bent.

In step S103, the planarization head 120 is driven in the −z-axis direction to bring the superstrate 108 into contact with the droplets of the curable composition 124 on the substrate 102. At this time, the positive pressure P is still held, and the adsorption pressure to the pressure space 148 is also continuously applied.

As the contact between the superstrate 108 and the substrate 102 progresses, the positive pressure P may be increased or maintained to control the curvature of a noncontact region of the superstrate 108.

As the superstrate 108 gradually comes into contact the substrate 102, the contact region of the superstrate 108 becomes planarized to match the substrate 102, while a curvature amount of the noncontact region decreases.

Therefore, in order to improve filling of the curable composition 124, it is necessary to control the curvature amount by controlling the positive pressure P. As the contact further progresses, the planarization head 120 is finally driven in the −z-axis direction until the entire surface of the superstrate 108 becomes flat.

In the final stage, since the positive pressure P becomes unnecessary, the positive pressure P is adjusted to be equal to atmospheric pressure or released. However, an adsorption pressure to the pressure space 148 remains applied.

In step S104, a film layer formed by the curable composition 124 with which a space between the superstrate 108 and the substrate 102 is filled is cured. For example, the film layer is cured by radiating UV light from the radiation source 126 in FIG. 1 along the exposure path 128. As described above, the plate 130 is transparent to the UV light so that the plate 130 does not interfere in the curing process.

As another example of step S104, the superstrate 108 may be released from the plate 130 and may be transported to a separate UV irradiation apparatus at a different position with the superstrate 108 integrated with the substrate, so that the curable composition 124 at a transport destination is cured with the UV irradiation apparatus at the transport destination.

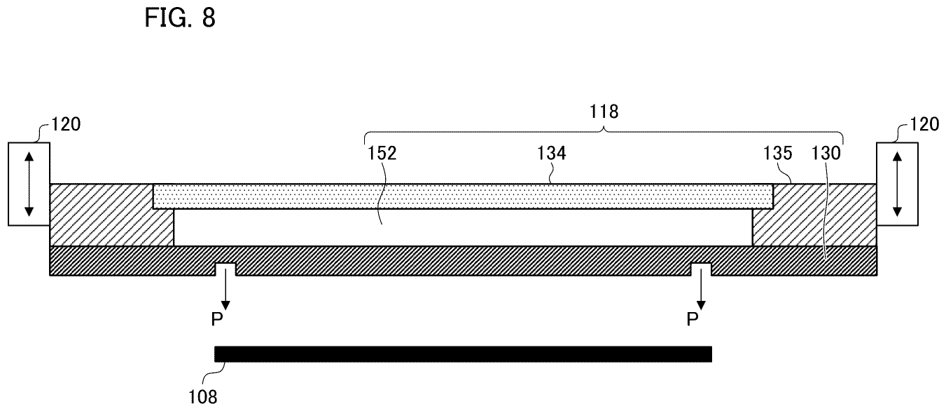

In that case, when the superstrate 108 is released from the plate 130, the adsorption pressure in the pressure space 148 is turned off. If an adhesive force between the superstrate 108 and the plate 130 due to the contact region is strong, a positive pressure may be applied to the pressure space 148 (adsorption portion), as illustrated in FIG. 8, to facilitate the releasing. That is, the pressure control unit may apply the positive pressure to the pressure space 148 (adsorption portion) of the holding unit when the member is released from the holding unit.

FIG. 8 is a diagram illustrating an example of a schematic cross-section of the chuck assembly when the superstrate 108 is released from a plate 130. As described above, after the superstrate 108 is released from the plate 130, the superstrate 108, the film layer, and the substrate 102 may be transported in an integrated state to a UV irradiation apparatus located at a separate position. Then, in the destination UV irradiation apparatus at a transport destination, the curing process may be performed on the film layer by radiating a UV light.

In the above UV irradiation apparatus at the transport destination, as described above, the film layer may be cured by radiating the UV light through the superstrate 108. After the curing is complete, the integrated state of the superstrate 108, the cured film layer, and the substrate 102 may be returned to an original position of the planarization system 100.

Then, at the original position, the superstrate 108 may be adsorbed again onto the plate 130 by applying an adsorption pressure to the pressure space 148, and then the process may proceed to step S105.

When the superstrate 108 is released from the plate 130 in step S104 as described above, either or both of the superstrate 108 and the plate 130 may become charged, and surrounding foreign particles may be attracted due to an electrostatic force.

Accordingly, it is desirable to perform the above releasing process while removing electricity using an ionizer (not illustrated). That is, an electricity removing unit that removes electricity of at least one of the member and the holding unit when the member and the holding unit are released may be provided.

Also, when UV light is radiated using a UV irradiation apparatus located at a different position as described above, the plates 130, 131, and 132, the cover 134, or the like may not be made of materials through which UV light is transmitted, and the radiation source 126 or the exposure path 128 is not required.

Subsequently, in step S105, the superstrate 108 is peeled off from the cured film layer. When peeling, the planarization head 120 may be driven in the z-axis direction to lift the superstrate 108 upward and become away from the substrate 102, or the substrate may be lowered in the −z-axis direction.

Meanwhile, the adsorption pressure to the pressure space 148 is held so that the plate 130 continues to be adsorbed to the superstrate 108. At this time, a separation process may be assisted by applying a negative pressure to the space 152 and deforming the lower surface of the superstrate 108 into a recess shape.

That is, the pressure control unit may deform both the plate 130 (or 131 or 132) that is the holding unit and the superstrate 108 that is the member into a projection shape in a direction opposite to the curable composition.

As described above, the present disclosure has been detailed based on embodiments. However, the present disclosure is not limited to these embodiments. Various modifications and combinations of the above-described embodiments may be made based on the spirit of the present disclosure, and such modifications are not excluded from the scope of the present disclosure. Moreover, parts of the above-described embodiments may be appropriately combined.

The present disclosure also includes implementations in which the functions of the above embodiments are implemented using at least one processor such as a CPU, a memory, and a circuit (for example, an ASIC). Distributed processing may also be employed using a plurality of processors.

In order to implement some or all of the controls in the above embodiments, a computer program that implements the described functions may be supplied to a film forming apparatus or a similar apparatus via a network or various types of storage media.

The computer (or a CPU, an MPU, or the like) in the film forming apparatus or another apparatus may read and execute the program. In that case, the program itself and the storage medium storing the program configure part of the present disclosure.

### OTHER EMBODIMENTS

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

This application claims the benefit of Japanese Patent Application No. 2024-160363, filed Sep. 17, 2024, which is hereby incorporated by reference herein in its entirety.

What is claimed is:

1. A film forming apparatus that forms a film of a curable composition on a substrate by bringing a member into contact with the curable composition, the film forming apparatus comprising:
a holding unit configured to adsorptively hold the member while coming into contact with a central portion of the member; and
a pressure control unit configured to apply a pressure to a surface of the holding unit opposite to a surface holding the member to deform the holding unit and the member.

2. The film forming apparatus according to claim 1, wherein the pressure control unit deforms both the holding unit and the member into a projection shape toward the curable composition.

3. The film forming apparatus according to claim 1, wherein the pressure control unit deforms both the holding unit and the member into a projection shape toward a side opposite to the curable composition.

4. The film forming apparatus according to claim 1, wherein an amount of deflection of the central portion of the member in response to the pressure is 0.01 to 1 μm/Pa.

5. The film forming apparatus according to claim 4, wherein the amount of deflection of the central portion of the member in response to the pressure is 0.01 to 0.1 μm/Pa.

6. The film forming apparatus according to claim 1, wherein a composite bending rigidity in the central portion of the member and a central portion of the holding unit is 1 to 200 Pa·m³.

7. The film forming apparatus according to claim 1, wherein a bending rigidity of a central portion of the holding unit is set in accordance with a bending rigidity of the member so that a composite bending rigidity of the central portions of the holding unit and the member falls within a predetermined range.

8. The film forming apparatus according to claim 1, wherein by making a rigidity of the holding unit nonuniform, overall rigidity uniformity in a state where the member is held is enhanced.

9. The film forming apparatus according to claim 8, wherein by making a thickness of a region of the holding unit corresponding to a shape of the member nonuniform, the rigidity of the holding unit is made nonuniform, and the overall rigidity uniformity in the state where the member is held is enhanced.

10. The film forming apparatus according to claim 8, wherein by constructing the holding unit using a plurality of plates each having a nonuniform rigidity in combination, the overall rigidity uniformity of the holding unit in the state where the member is held is enhanced.

11. The film forming apparatus according to claim 1, wherein the member and the holding unit facing the member are formed of a light-transmissive material.

12. The film forming apparatus according to claim 1, wherein the pressure control unit applies a positive pressure to an adsorption portion of the holding unit when the member is released from the holding unit.

13. The film forming apparatus according to claim 1 further comprising an electricity removing unit that removes electricity of at least one of the member and the holding unit when the member is released from the holding unit.

14. The film forming apparatus according to claim 1 further comprising an imprint apparatus configured to form a film with unevenness by bringing a mold into contact with the curable composition disposed on the substrate, the member including the mold, and the mold having an uneven contact surface coming into contact with the curable composition.

15. The film forming apparatus according to claim 1 further comprising a planarization device configured to form a flat film by bringing a planarization member into contact with the curable composition disposed on the substrate, the member including the planarization member, and a main portion of a contact surface of the planarization member coming into contact with the curable composition having a flat surface.

16. A film forming method of forming a film of a curable composition on a substrate by bringing a member into contact with the curable composition, the film forming method comprising:
adsorptively holding the member to a holding unit while bringing the holding unit into contact with a central portion of the member; and
applying a pressure to a surface of the holding unit opposite to a surface holding the member to deform the holding unit and the member.

17. A method of manufacturing an article, the method comprising:
forming a film of a curable composition on a substrate using the film forming apparatus according to claim 1;
processing the substrate on which the film is formed in the forming; and
manufacturing the article from the substrate processed in the processing.

18. The method of manufacturing an article according to claim 17, wherein the article includes a semiconductor device.
